(19) United States
(12) Patent Application Publication
(10) Pub. No.: US 2025/0161858 A1
(43) Pub. Date: May 22, 2025

(54) INLINE FILTRATION FOR STEAM APPLICATIONS

(71) Applicant: Applied Materials, Inc., Santa Clara, CA (US)

(72) Inventors: Chaitanya Anjaneyalu PRASAD, Cupertino, CA (US); Wenfei ZHANG, San Jose, CA (US); Maryam SARKARAT, Santa Clara, CA (US); Naman APURVA, Patna (IN); Christopher S. OLSEN, Fremont, CA (US)

(21) Appl. No.: 18/953,898

(22) Filed: Nov. 20, 2024

(30) Foreign Application Priority Data
Nov. 20, 2023 (IN) 202341078608

(51) Int. Cl. B01D 46/54; B01D 39/20; B01D 46/42; C23C 8/04; C23C 8/16; H01L 21/02

(52) U.S. Cl. CPC B01D 46/54; B01D 39/2027; B01D 46/4263; C23C 8/04; C23C 8/16; H01L 21/02236; B01D 2273/20

(57) ABSTRACT

A method for selective oxidation of a substrate. The substrate is disposed in a chamber. A hydrogen containing gas is introduced to the chamber. The hydrogen containing gas is directed through a filter to the chamber. The filter is configured to filter particles greater than about 1 nm. The chamber is pressurized to a pressure of about 250 Torr to about 800 Torr while maintaining the hydrogen containing gas in the chamber. The chamber is heated to a predetermined temperature for a predetermined period of time while maintaining the hydrogen containing gas in the chamber. The substrate is selectively oxidized.

### CROSS-REFERENCE TO RELATED APPLICATIONS

This application claims priority to Indian Provisional Patent Application No. 202341078608, filed Nov. 20, 2023, the entirety of which is herein incorporated by reference.

### BACKGROUND OF THE DISCLOSURE

### Field of the Disclosure

Embodiments of the present disclosure generally relate to the field of semiconductor manufacturing and more specifically to a method and apparatus for the selective oxidation of a composite silicon/metal film.

### Description of the Related Art

In the manufacture of semiconductor devices, oxidation of silicon containing substrates plays a key role. For example, in a standard semiconductor device, a gate oxide layer is ordinarily situated over a substrate containing a source region, a drain region, and an intervening silicon or polysilicon region. Metal contacts are deposited over the source and drain regions, and a conductive layer deposited over the gate oxide. The entire structure is often depicted as a stack of layers. When a voltage is applied across the gate oxide generating an electric field oriented along an axis from the substrate, through the gate oxide, to the conductive layer, the electrical characteristics of the region between the source and drain region change, either allowing or stopping the flow of electrons between the regions. The gate oxide layer thus occupies a role in the structure of semiconductor devices.

Unfortunately, the oxide layer can be damaged during processing, where the oxide layer may be repaired by re-oxidizing the device. Re-oxidation creates a thin layer of oxide on the sides of the gate oxide and underlying silicon containing layers, repairing the edge damage. Because oxidizing other regions of the transistor may reduce conductivity and impair the device, oxidizing only certain materials in the device is beneficial. Selective oxidation, e.g., wet oxidation, dry oxidation, or steam oxidation, targets certain materials, such as silicon and oxides of silicon, while avoiding oxidation of other materials.

Unfortunately, steam is capable of dissolving particles and/or carrying particles via condensation and vaporization. As such, steam oxidation can introduce particles, e.g., dissolved organic particles, precursor particles, or sealing and/or seat valve particles, into the device and impairing the device functionality. Moreover, at high chamber pressures and high steam ratios, particle contamination may increase, limiting the operating conditions of the steam oxidation.

Thus, there is still a need for a selective oxidation process that uses steam oxidation without introducing particle contaminants into the oxide layer.

### SUMMARY OF THE DISCLOSURE

The present disclosure provides methods for selective oxidation of a substrate. The substrate is disposed in a chamber. A hydrogen containing gas is introduced to the chamber. The hydrogen containing gas is directed through a filter to the chamber. The filter is configured to filter particles greater than about 1 nm. The chamber is pressurized to a pressure of about 250 Torr to about 800 Torr while maintaining the hydrogen containing gas in the chamber. The chamber is heated to a predetermined temperature for a predetermined period of time while maintaining the hydrogen containing gas in the chamber. The substrate is selectively oxidized.

The present disclosure also provides methods for processing a substrate. The substrate is disposed in a rapid thermal processing (RTP) chamber. A non-reactive gas is introduced to the chamber. A hydrogen containing gas is introduced to the chamber. The hydrogen containing gas is directed through a filter to the chamber. The filter is configured to filter particles greater than about 1 nm. The chamber is pressurized to a pressure of greater than 250 Torr while maintaining the hydrogen containing gas in the chamber. The chamber is heated to a processing temperature while maintaining the hydrogen containing gas in the chamber. The substrate is selectively oxidized.

The present disclosure also provides methods of processing a substrate. The methods include at least a silicon containing layer and a metal layer, in a chamber. A hydrogen containing gas is introduced to the chamber. The hydrogen containing gas is directed through a filter to the chamber. The filter is configured to filter particles greater than about 1 nm. The chamber is pressurized to a pressure of greater than 250 Torr while maintaining the hydrogen containing gas in the chamber. The silicon containing layer is selectively oxidized.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of scope, for the disclosure may admit to other equally effective embodiments.

FIG. 1 is an illustration of a rapid thermal heating apparatus, according to embodiments of the disclosure.

FIG. 2A is an illustration of a filtration module, according to embodiments of the disclosure.

FIG. 2B is an illustration of a heated filtration module, according to embodiments of the disclosure.

FIG. 3 is a flowchart that illustrates an embodiment of selective oxidation, according to embodiments of the disclosure.

FIG. 4A is a cross-sectional view of a substrate prior to applying a selective oxidation process according to one embodiment of the present disclosure.

FIG. 4B is a cross-sectional view of a substrate following application of a selective oxidation process according to one embodiment of the present disclosure.

FIG. 5 is a graph showing concentration of particles after steam oxidation.

FIG. 6 is a graph showing concentration of particles after steam oxidation with a filtration module.

FIG. 7 is a graph showing concentration of particles after steam oxidation with a filtration module or without a filtration module.

### DETAILED DESCRIPTION

The present disclosure describes a method for selectively oxidizing silicon containing materials in a substrate using a filtration module. The filtration module can reduce a concentration of particles in the oxide layer and/or the device, improving device performance. Moreover, the filtration module may be operated to prevent a pressure drop, such that the temperature and pressure of the steam (e.g., hydrogen-containing steam) being introduced into the processing chamber is maintained to promote efficient steam oxidation. While the disclosure will be described below in reference to a rapid thermal heating chamber, it is to be understood that the disclosure may be practiced in one or more other chambers as well.

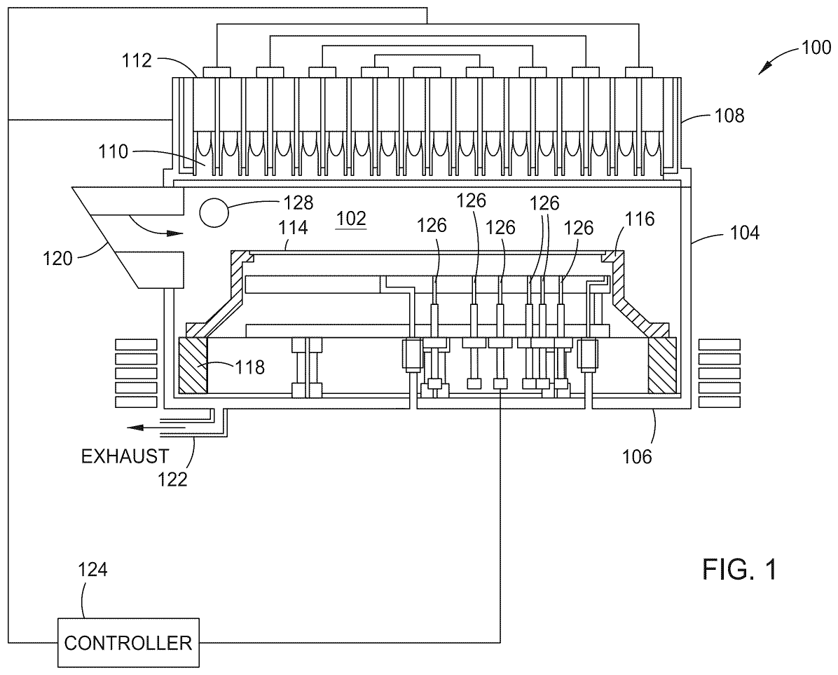

FIG. 1 illustrates a rapid thermal heating apparatus 100 that can be used to carry out the process of the present disclosure. The apparatus features a process chamber 102 that may be evacuated or filled with selected gases, and a side wall 104 and bottom enclosure 106. The upper portion of the sidewall is sealed against a light pipe assembly 108, from which radiant energy is directed into the chamber. The light pipe assembly 108 includes a plurality of tungsten halogen lamps 110, for example Sylvania EYT lamps, each mounted into a light pipe 112 which may be made of stainless steel, brass, aluminum, or other metal.

A substrate 114 is supported within the process chamber 102 by a support ring 116 that contacts the edge of the substrate. The support ring 116 is made of a material capable of withstanding high temperatures, such as silicon carbide, without imparting impurities to the substrate. The support ring 116 may be mounted on a rotation cylinder 118. In one embodiment, a quartz rotation cylinder capable of rotating the support ring and substrate thereon may be used. Rotation of the substrate promotes uniform temperature distribution.

Process gases may be admitted to the chamber through representative portal 120, and exhaust evacuated through representative portal 122. In some embodiments, multiple gas feed and exhaust portals may be used. A temperature controller 124 receives measurements from pyrometers 126 and adjusts power to lamps 110 to achieve even heating.

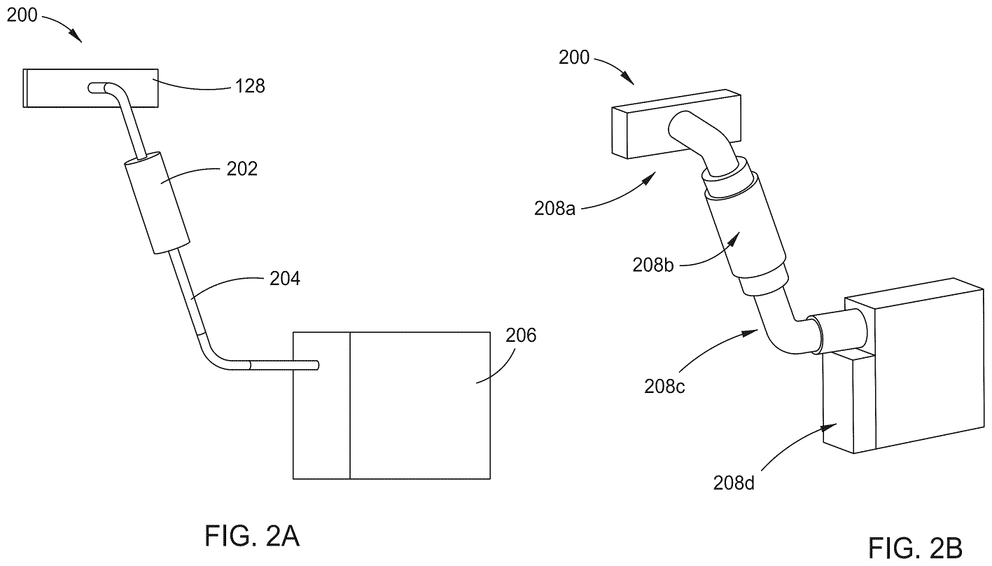

A side inject 128 may be fluidly coupled to the process chamber 102. The side inject 128 may include one or more nozzle or inlet ports, or alternatively a showerhead to inject one or more gases, e.g., hydrogen, steam, oxygen, and/or isotopes thereof. In an embodiment, the side inject 128 is fluidly coupled to a filtration module (not shown), which is described below, with reference to FIG. 2. For example, the filtration module (not shown), may inject one or more gases through the side inject 128.

FIG. 2A illustrates a filtration module 200. The filtration module 200 can include a filter 202. The filter 202 can include stainless steel, such as a stainless steel medium, e.g., mesh or wool, through which fluid is directed to facilitate filtering. The filter 202 can include a separator, mesh, or other size separation component suitable for separating particles or contaminants based on a size of the particle. In an embodiment, the filter 202 may prevent particles having a size of greater than 1 nm from passing through the filter 202, e.g., greater than 1 nm, greater than 5 nm, greater than 10 nm, greater than 100 nm, greater than 1 μm, greater than 10 μm, greater than 100 μm, or more. Without being bound by theory, by preventing particles having a size of greater than 1 nm or larger passing through, a reduction of particle contamination in the processing chamber (and thus, on a substrate) may occur, increasing device performance.

In an embodiment, the filter 202 may include a pressure of about 400 Torr to about 600 Torr, e.g., about 400 Torr to about 450 Torr, about 450 Torr to about 500 Torr, about 500 Torr to about 550 Torr, or about 550 Torr to about 600 Torr. The filter 202 may result in a pressure drop of about 1 Torr to about 10 Torr, e.g., about 1 Torr to about 3 Torr, about 3 Torr to about 6 Torr, about 6 Torr to about 9 Torr, or about 7 Torr to about 10 Torr.

The filter 202 may receive a gas from a carrier manifold 204. The carrier manifold 204 may direct one or more gases, e.g., steam, hydrogen, oxygen, and/or isotopes thereof, from a valve manifold 206 to the filter 202. The carrier manifold 204 may include any tube, casing, or flow path that can transport one or more gases, e.g., hydrogen, steam, oxygen, and/or isotopes thereof to the filter 202. The carrier manifold 204 may include a pressure of about 400 Torr to about 600 Torr, e.g., about 400 Torr to about 450 Torr, about 450 Torr to about 500 Torr, about 500 Torr to about 550 Torr, or about 550 Torr to about 600 Torr.

The carrier manifold 204 may receive the one or more gases from a valve manifold 206. The valve manifold 206 may include a plurality of valves, e.g., gate valves, butterfly valves, needle valves, diaphragm valves, pinch valves, check valves, gate valves, plug valves, or a combination thereof. The plurality of valves may include one or more sealing components and/or seats to prevent flow of the gas to the carrier manifold 204. In an embodiment, during operation, the plurality of valves may regulate and/or control an amount of flow of the one or more gases, e.g., steam, hydrogen, oxygen, or isotopes thereof into the carrier manifold 204.

While FIG. 2A shows one exemplary embodiment of the filter module 200, the filter module 200 may be oriented in any suitable manner, e.g., the filter 202 may be located downstream of the valve manifold 206, e.g., between the side inject 128 and the valve manifold 206. Alternatively, the filter 202 may be located upstream of the valve manifold 206 (not shown).

In an embodiment, the filtration module 200 can include one or more sensors (not shown). For example, the one or more sensors can include a pressure sensor. As a further example, the one or more sensors can include a temperature sensor. In an embodiment, the one or more sensors can be located at any location in the filtration module 200.

FIG. 2B illustrates a filtration module 200 including one or more heaters, shown as heaters 208a, 208b, 208c, or 208d. In an embodiment, any of the side inject, filter, carrier manifold, and/or valve manifold may be heated by heaters 208a, 208b, 208c, or 208d. The heaters may increase the temperature of the filtration module 200 to a temperature of about 80° C. to about 140° C., e.g., about 80° C. to about 90° C., about 90° C. to about 100° C., about 100° C. to about 110° C., about 110° C. to about 120° C., about 120° C. to about 130° C., about 130° C. to about 140° C. Without being bound by theory, the heaters 208a-d may reduce condensation in the filtration module 200, thereby reducing the amount of dissolved contaminants in the one or more gases. In one example, the heaters 208a, 208b, 208c, or 208d are jackets which may be heated using a resistive heaters or fluids.

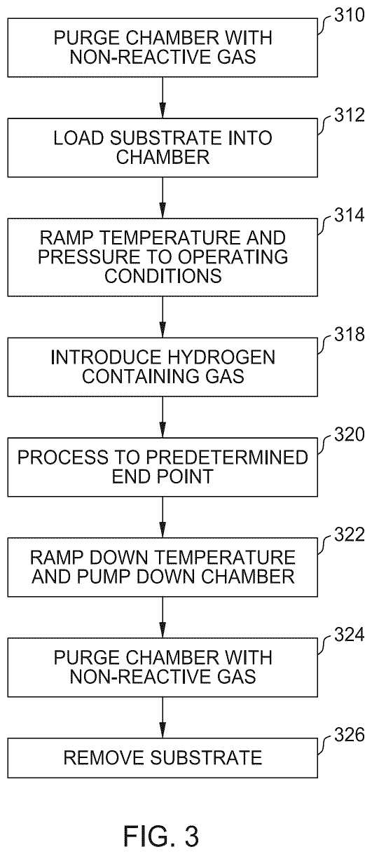

FIG. 3A is a flowchart that illustrates a method of selectively oxidizing a substrate according to the present disclosure. The first operation in the process 310 is to purge any reactive gases from the chamber. Purging avoids any unwanted chemical reactions on the substrate during preparatory phases of the oxidation treatment when temperatures and pressures may be elevated. It is an objective of the present disclosure to oxidize only silicon containing layers of a substrate comprising silicon containing layers, metal layers, and optionally barrier or capping layers. To accomplish this objective, composition of gases in the process chamber may be controlled during any process operation featuring elevated temperature or pressure. The purge is accomplished by pumping all gases out of the chamber and then flowing a non-reactive gas into the chamber to create a non-reactive gas atmosphere in the process chamber. The non-reactive gas does not react with any substrate material during processing. Gases which are non-reactive in the process of the present disclosure include, but are not limited to, nitrogen gas (N₂), helium (He), argon (Ar), neon (Ne), and xenon (Xe).

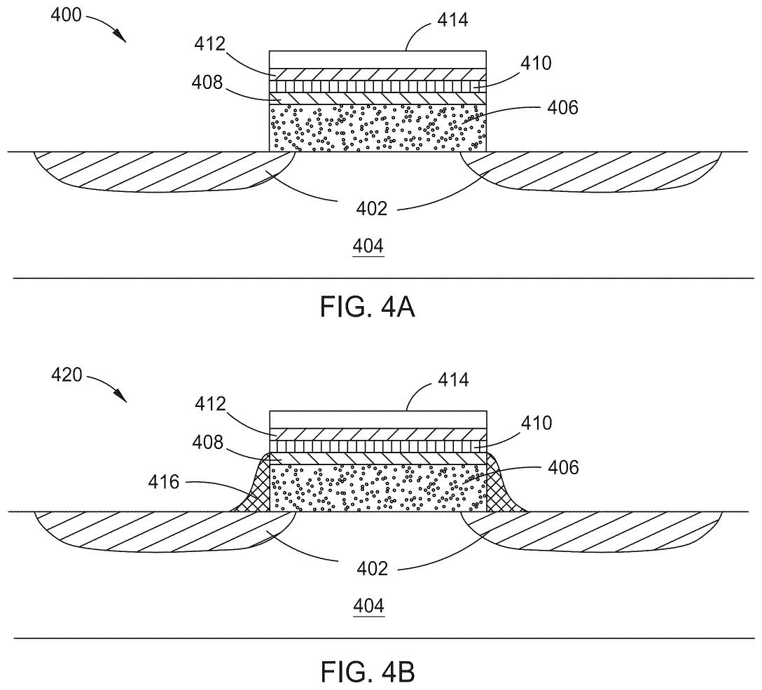

A substrate having multiple layers of silicon containing materials, metals, and optionally barrier or capping layers is disposed within the chamber in the next operation of the process 312. The layers may be patterned to form device structures, such as transistors, on the substrate. FIG. 4A illustrates a typical gate transistor structure 400. Doped silicide regions 402 are disposed within a polysilicon domain 404 of the substrate. The doped silicide regions 402 form source and drain regions for the transistor. Over the doped silicide regions 402, multiple layers of polysilicon 406, gate oxide 408, barrier material 410, metal contacts 412, and protective or hard mask material 414 may be deposited. Additionally, and not shown, metal contacts may be deposited directly atop the doped silicide regions, with or without barrier or nucleation layers between. The process of the present disclosure selectively oxidizes only the polysilicon and gate oxide layers, along with other silicon containing areas of the substrate, without oxidizing the metal or other layers.

The substrate may be introduced to the chamber through a slit valve in the process chamber. A transfer robot configured as part of a processing cluster or platform may be used to load the substrate into the chamber. Alternately, a tray loader may be used with a cartridge device to load and unload multiple substrates consecutively. Furthermore, a carousel arrangement may be used to transport substrates into and out of the process chamber as part of a rotary processing cluster, or a linear processing assembly may be used.

Referring once again to FIG. 3A, the substrate supported on the support ring in the process chamber under a non-reactive atmosphere is next subjected to a temperature and pressure ramp-up step 314. Hydrogen containing gas, e.g., steam filtered through the filtration module, may be fed to the process chamber via the side inject prior to ramping-up temperature and pressure. Alternately, the non-reactive atmosphere may be maintained during the ramp-up by flowing non-reactive gas into and out of the process chamber. Pressure in the chamber may be precisely controlled and any fugitive emissions that may escape the substrate removed by the flowing gases as temperature increases. Temperature and pressure may be ramped in any pattern, simultaneously or consecutively, up to the desired predetermined process conditions. The temperature ramp may be designed to confer the added benefit of annealing any of the various layers of the substrate. For example, the pressure may be about 150 Torr to about 800 Torr, e.g., about 250 Torr to about 600 Torr or about 400 Torr to about 500 Torr. As a further example, the temperature may be greater than 700° C., e.g., about 800° C. to about 1000° C. or about 900° C. to about 1000° C.

Referring again to FIG. 3A, a hydrogen containing gas, e.g., steam filtered through the filtration module, may be fed to the process chamber before or after ramping-up temperature and pressure in step 318. Without being bound by theory, water molecules may diffuse into the silicon containing material crystal network, liberating hydrogen at Si—Si or Si—SiO₂ bonds. Processing continues in operation 320 until a predetermined end point is reached, such as a certain amount of time. Temperature is reduced and the chamber evacuated in operation 322 to remove reactive species. A non-reactive gas is once again charged to the chamber in step 324 to complete the process, after which the substrate is removed in operation 326.

In another alternate embodiment, hydrogen containing gas, e.g., filtered steam from the filtration module, may be introduced to the chamber before reaching the desired temperature and pressure points, with the potential advantage of passivating any metal layers on the substrate, further reducing the oxidation potential of the metals. In other embodiments, a non-reactive or carrier gas may be used with the hydrogen containing gas, e.g., filtered steam from the filtration module, and may be fed separately or with either gas. The gases may be mixed outside the reaction chamber or fed individually to the chamber. Use of a non-reactive gas may promote mixing and selectivity.

The reaction is driven by the temperature and pressure in the reaction zone. The reaction zone is heated by convection from the hot substrate and by energy released from the oxidation reaction. Temperatures required to drive the reaction are thus found in the immediate vicinity of the substrate surface. In some embodiments, the reaction may be confined to a zone up to 1 cm from the substrate surface. Without being bound by theory, temperatures above 700° C. may assist in promoting selective oxidation reactions. In an embodiment, temperature may be controlled through sensors disposed in the chamber and connected to a temperature controller that varies power to the heat lamps.

In an embodiment, the hydrogen-containing gas is maintained in the processing chamber for a set amount of time. In an embodiment, a thin film of oxide growth on the silicon containing materials of the substrate may be achieved, e.g., about 20 Angstroms to about 50 Angstroms. For example, the set amount of time may include a duration of about 1 to about 5 minutes. FIG. 4B illustrates a device structure 420 after selective oxidation has been performed. Oxide layers 416 may grow adjacent to silicon containing layers of the structure. With the process of the present disclosure, oxidation selectivities of polysilicon and silicon dioxide relative to tungsten metal up to 99.6% may be obtained. When the end point is reached, temperature may be ramped down and the reaction chamber may be pumped out and non-reactive gas charged. The chamber may be purged briefly to ensure no potentially reactive gases remain to degrade the substrate, and then the substrate is removed from the chamber for further processing.

The foregoing process may be used to selectively oxidize many silicon containing materials on a substrate with a reduced amount of particle contamination. Such silicon containing materials include, but are not limited to, polysilicon (or polycrystalline silicon), doped silicon, microcrystalline silicon, doped microcrystalline silicon, amorphous silicon, doped amorphous silicon, generic silicon, doped or undoped, not fitting any of the former labels, partially oxidized silicon materials substantially comprising silicon dioxide (SiO₂), and combinations thereof. Likewise, many popular metal conductors and barrier or protective layers may be safely exposed to this process. Metal layer compositions which will not be oxidized under such conditions include, but are not limited to, aluminum (Al), copper (Cu), tungsten (W), tungsten nitride (WN), titanium (Ti), titanium nitride (TiN), tantalum (Ta), tantalum nitride (TaN), tantalum carbonitride (TaCN), and combinations thereof.

### EXAMPLES

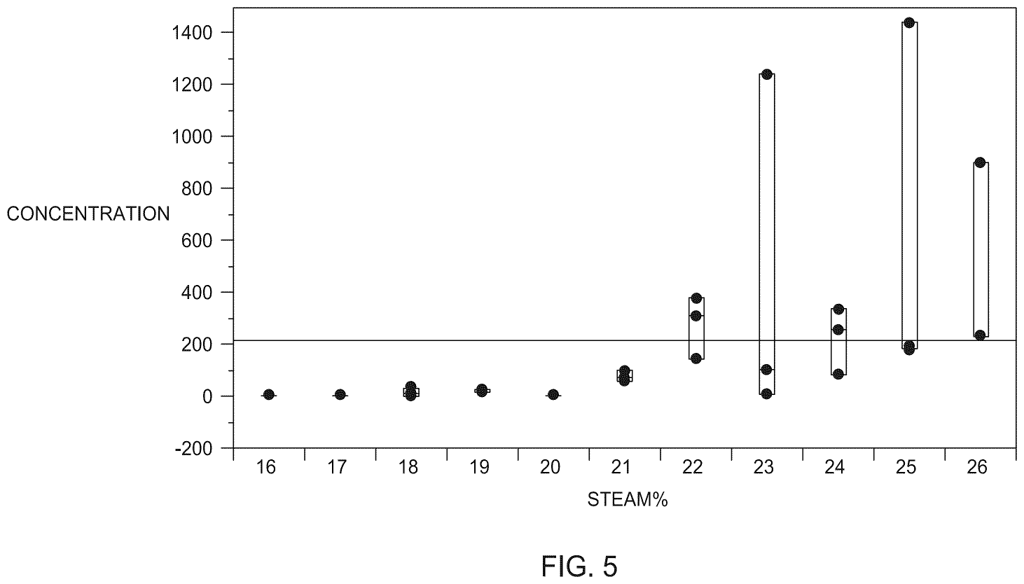

Now referring to FIG. 5, a concentration of particle contaminants with varying concentrations of unfiltered steam was determined. Particles were measured based on a 32 nm section, where a steam percentage of greater than 22% v/v of the side inject gas resulted in a concentration of particle contaminants being on average greater than 200 particles. Moreover, as the steam percentage increased the concentration of particle contaminants increased. For example, at 25% v/v of the side inject gas, the concentration of particle contaminants increased to a maximum of 1400 particles.

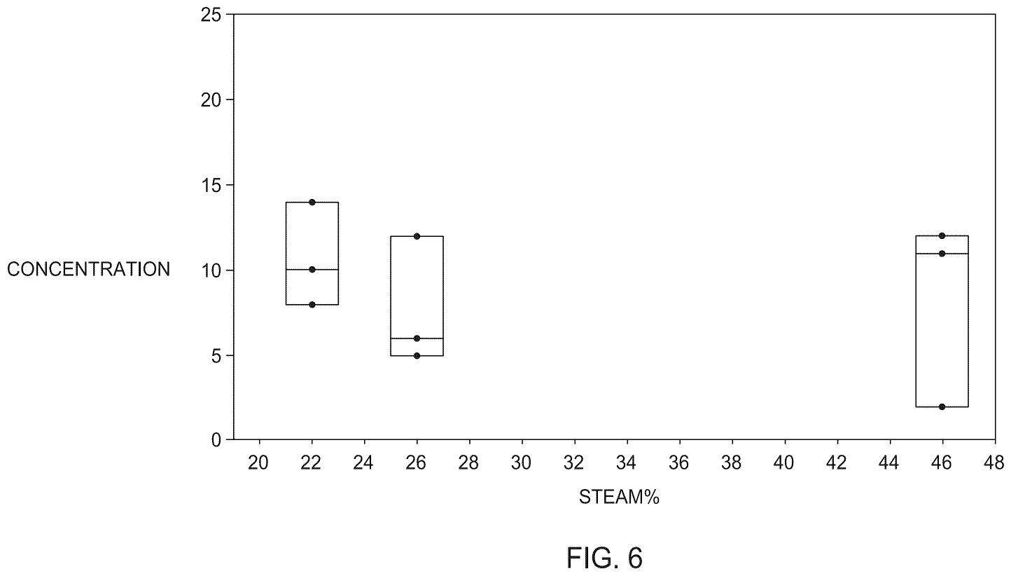

Now referring to FIG. 6, a concentration of particle contaminants with varying concentrations of filtered steam was determined. Particles were measured based on a 32 nm section, where a steam percentage of 22% v/v of the side inject gas resulted in a concentration of particle contaminants being on average about 7 particles to about 14 particles. Moreover, as the steam percentage increased the concentration of particle contaminants remained below 15 particles. For example, at 46% v/v of the side inject gas, the concentration of particle contaminants was about 2 particles to about 12 particles. Without being bound by theory, filtered steam allowed for the reduction of particle contaminants even when operating at higher steam concentrations.

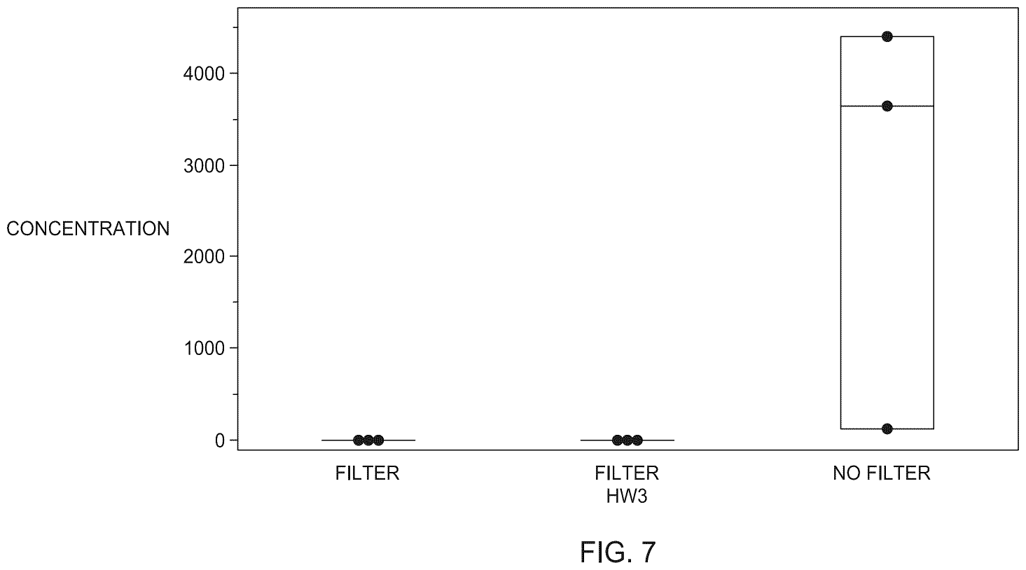

Now referring to FIG. 7, a concentration of particle contaminants with a filtration module located downstream of the valve manifold and upstream of the valve manifold was determined. A filtration module located downstream of the valve manifold resulted in a concentration of particle contaminants of about 0 particles in a 32 nm section. Moreover, a filtration module located upstream of the valve manifold resulted in a concentration of particle contaminants of about 0 particles in a 32 nm section. Alternatively, where no filtration module was implemented in the apparatus 100, the concentration of particle contaminants was about 3500 to about 4300 particles in a 32 nm section. Without being bound by theory, a location of the filtration module that is either upstream or downstream of the valve manifold may reduce a concentration of the particle contaminants, thereby increasing device performance.

Embodiments of the present disclosure relating to a method and apparatus for the selective oxidation of a composite silicon/metal film have been described. A filtration module can reduce a concentration of particles in the oxide layer and/or the device, improving device performance. Moreover, the filtration module may be operated to prevent a pressure drop, such that the temperature and pressure of the steam being introduced into the processing chamber is maintained to promote efficient steam oxidation.

While the foregoing is directed to embodiments of the present disclosure, other and further embodiments of the disclosure may be devised without departing from the basic scope thereof. The scope of the disclosure is defined by the claims that follow.

1. A method of selectively oxidizing materials of a substrate, comprising:
disposing the substrate in a chamber;
introducing a hydrogen containing gas to the chamber, wherein the hydrogen containing gas is directed through a filter to the chamber, and wherein the filter is configured to filter particles greater than about 1 nm;
pressurizing the chamber to a pressure of about 250 Torr to about 800 Torr while maintaining the hydrogen containing gas in the chamber; and
heating the chamber to a predetermined temperature for a predetermined time while maintaining the hydrogen containing gas in the chamber, and
selectively oxidizing the substrate.

2. The method of claim 1, wherein hydrogen containing gas is steam.

3. The method of claim 1, wherein the predetermined temperature is greater than about 700° C.

4. The method of claim 1, wherein the filter is configured to filter particles greater than about 5 nm.

5. The method of claim 1, wherein the filter comprises stainless steel.

6. The method of claim 1, wherein the filter comprises one or more heaters.

7. The method of claim 6, wherein the heaters are configured to heat the filter to about 80° C. to about 140° C.

8. The method of claim 1, wherein selectively oxidizing the substrate comprises oxidizing only a silicon containing material.

9. The method of claim 8, wherein the silicon containing materials comprise silicon, doped silicon, polysilicon, doped polysilicon, amorphous silicon, doped amorphous silicon, microcrystalline silicon, doped microcrystalline silicon, silicon dioxide (SiO₂), or combinations thereof.

10. The method of claim 1, wherein the filter comprises a pressure of about 400 Torr to about 600 Torr when directing the hydrogen containing gas therethrough.

11. The method of claim 1, further comprising producing a pressure drop of about 1 Torr to about 10 Torr in the filter when directing the hydrogen containing gas therethrough.

12. A method of processing a substrate, comprising:
disposing the substrate in a rapid thermal processing (RTP) chamber;
introducing a non-reactive gas to the chamber;
introducing a hydrogen containing gas to the chamber, wherein the hydrogen containing gas is directed through a filter to the chamber, and wherein the filter is configured to filter particles greater than about 1 nm;
pressurizing the chamber to a pressure of greater than about 250 Torr while maintaining the hydrogen containing gas in the chamber;
heating the chamber to a processing temperature while maintaining the hydrogen containing gas in the chamber e; and
selectively oxidizing the substrate.

13. The method of claim 12, wherein hydrogen containing gas is steam.

14. The method of claim 12, wherein the filter comprises stainless steel.

15. The method of claim 12, wherein the filter comprises one or more heaters configured to heat the filter to about 80° C. to about 140° C.

16. The method of claim 12, wherein selectively oxidizing the substrate comprises oxidizing only a silicon containing material.

17. The method of claim 12, wherein the filter comprises a pressure of about 400 Torr to about 600 Torr when directing the hydrogen containing gas therethrough.

18. The method of claim 12, further comprising producing a pressure drop of about 1 Torr to about 10 Torr in the filter when directing the hydrogen containing gas therethrough.

19. A method of processing a substrate, comprising at least a silicon containing layer and a metal layer, in a chamber, comprising:
introducing a hydrogen containing gas to the chamber, wherein the hydrogen containing gas is directed through a filter to the chamber, and wherein the filter is configured to filter particles greater than about 1 nm;
pressurizing the chamber to a pressure of greater than 250 Torr while maintaining the hydrogen containing gas in the chamber; and
selectively oxidizing the silicon containing layer.

20. The method of claim 19, wherein hydrogen containing gas is steam.
